(19) United States
(12) Patent Application Publication
(10) Pub. No.: US 2010/0117708 A1
(43) Pub. Date: May 13, 2010

(54) Voltage Level Converter without Phase Distortion

(76) Inventor: Wei-Ta Chen, Hsin-Chu (TW)

Correspondence Address: SLATER & MATSIL, L.L.P., 17950 PRESTON ROAD, SUITE 1000, DALLAS, TX, 75252, US

(21) Appl. No.: 12/268,809

(22) Filed: Nov. 11, 2008

(51) Int. Cl. H03L 5/00

(52) U.S. Cl. 327/333

(57) ABSTRACT

A voltage level converter with reduced signal phase distortion is provided. The voltage level converter includes a level shifting circuit followed by a unit interval retrieval circuit. The level shifting circuit takes complementary input voltage signals and converts to signals with different voltage levels. The unit interval retrieval circuit responds to the output complementary signals from the level shifting circuit and generates one or more output signals that restore the period of the original input voltage signals with no or negligible phase distortion.

### TECHNICAL FIELD

This invention relates generally to a voltage level converter and, more particularly, to eliminating signal phase distortions generated in a voltage level converter used in a semiconductor integrated circuit.

### BACKGROUND

In an advanced integrated circuit (IC), such as an IC having a system-on-a-chip (SOC) configuration, millions or ten of millions or more semiconductor devices are typically interconnected to form a complex electronic system, which may be used to perform various signal processing functions, such as wireless communication, real-time multimedia streaming, etc. An advanced IC with this level of complexity typically comprises multiple functional modules, each of which performs a specific signal processing task, and the combined functional modules fulfill the pre-determined overall system function. As an example, an SOC may comprise one or more embedded microprocessors for processing the input signals, one or more embedded memory modules, such as static random access memory (SRAM), for storing data processed from the microprocessors, one or more input/output (I/O) interfaces between the outside world signals and the IC, and I/O interfaces between the various on-chip functional modules.

Different supply voltages are typically needed for the various functional circuit modules to perform their desired functions. For example, an embedded SRAM module may require a lower supply voltage, such as 0.9 V for its operation, an embedded processor may need an intermediate supply voltage of 1.2 V, while a higher supply voltage of 2.5 V may be required by the I/O interface circuits. From a supply voltage point of view, an IC with such configuration is also generally referred to as a multiple-voltage system.

When combining multiple supply voltages on an IC, level converters (also typically referred to as level shifters) are generally required when a module at a lower supply voltage has to drive a module at a high voltage, and vise versa. FIG. 1 illustrates an existing level shifter used to convert voltage signals from one supply voltage domain in an IC to voltage signals under another supply voltage domain in the IC. Complementary input signals I and Ibar, which has a smaller amplitude, is level shifted to output signals Q and Qbar with a higher magnitude (e.g., VDDH). The complementary output signals Q and Qbar are generated at a pair of complementary nodes.

FIG. 2a illustrates that the transitions of the complementary output signals Q and Qbar follow the transitions of input signals I and Ibar. It is realized, however, that the delay of this level converter is quite sensitive to the variations of supply voltage, transistor sizing, and temperature (also generally referred to as PVT variations). As a result, the input signals may be degraded or distorted after passing the level converter. As an example, in FIG. 2a, the original signal has a period T_{org}, and the translated signal has a period Tₜᵣₗ, each measured corresponding to the mid-points of the signal transition edges. Due to PVT variations, the rising delay T_{dr} and falling delay T_{df} are different, hence causing the phase distortion that results in the unfavorable mismatch between periods Tₜᵣₗ and T_{org}.

FIG. 2b illustrates a consequence of phase distortion described above. An input eye diagram is plotted to illustrate the signal margin in an input signal waveform I and Ibar, where the crossing points are near the mid-points of the input signal transition edges. However, the cross points of the complementary output signals Q and Qbar are greatly shifted from the locations near the mid-points of their transition edges, where the inclination of the rising and falling edges of the output signal fluctuates due to the phase distortion. As a result, the eye diagram in the output signal waveform is distorted so that a satisfactory margin relative to the eye diagram may not be maintained.

### SUMMARY OF THE INVENTION

These and other problems are generally solved or circumvented, and technical advantages are generally achieved, by preferred embodiments of the present invention which provides a voltage level converting circuit with reduced signal phase distortion. The voltage level converting circuit includes a level shifting circuit followed by a unit interval retrieval circuit. The level shifting circuit takes complementary input voltage signals and converts to signals with different voltage levels. The unit interval retrieval circuit responds to the output signals from the level shifting circuit and generates one or more output signals that restore the period of the original input voltage signals with no or negligible phase distortion.

In accordance with one aspect of the present invention, a voltage level converting circuit comprises a voltage level shifting circuit. The voltage level shifting circuit responds to a first input voltage signal and a second input voltage signal and outputs a third and a fourth voltage signal, wherein the first input voltage signal and the second input voltage signal are at a first voltage level and complementary to each other, and wherein the third and fourth voltage signals are at a second voltage level. The voltage level converting circuit also comprises a unit interval retrieval circuit. The unit interval retrieval circuit responds to the third and the fourth voltage signals and outputs a fifth voltage signal at the second voltage level, wherein the period of the fifth voltage signal is substantially similar to that of the first voltage signal.

In accordance with another aspect of the present invention, a voltage level converting circuit comprises a voltage level shifting circuit. The voltage level shifting circuit generates a first voltage signal and a second voltage signal in response to mutually complementary input voltage signals, wherein the first voltage signal and the second voltage signal have a different voltage level from the input voltage signals. The voltage level converting circuit also comprises a unit interval retrieval circuit. The unit interval retrieval circuit responds to the first voltage signal and the second voltage signal and outputs a first output voltage signal that has a period substantially similar to that of the input voltage signals. Also, a first voltage state of the first voltage signal and a second voltage state of the second voltage signal set the first output signal to the first voltage state.

In accordance with yet another aspect of the present invention, a voltage level converting circuit comprises a voltage level shifting circuit. The voltage level shifting circuit responds to a first input voltage signal and a complementary second input voltage signal at a first voltage level and outputs a third voltage signal and a complementary fourth voltage signal at a second voltage level. The voltage level converting circuit also comprises a unit interval retrieval circuit. The unit interval retrieval circuit responds to the third voltage signal and the complementary fourth voltage signal and outputs a first output voltage signal at the second voltage level, wherein the period of the first output voltage signal is substantially similar to that of the first input voltage signal. Also, a rising edge of the second input signal triggers the third voltage signal to change from a high voltage state to a low voltage state, which triggers the fourth voltage signal to change from a low voltage state to a high voltage state, which triggers the first output voltage signal to change from a high voltage state to a low voltage state. Furthermore, a rising edge of the first input signal triggers the fourth voltage signal to change from a high voltage state to a low voltage state, which triggers the third voltage signal to change from a low voltage state to a high voltage state, which triggers the first output voltage signal to change from a low voltage state to a high voltage state.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a level shifter for generating a pair of complementary output signals, which may have a phase distortion;

FIGS. 2a-2b illustrate a phase distortion occurrence when a translated signal is generated from an original signal;

FIG. 3 illustrates a block diagram of an illustrative embodiment, wherein an output signal restores the period of an original input signal with no or negligible phase distortion;

FIG. 4 illustrates a timing diagram of input and output signals in an illustrative embodiment;

FIG. 5 illustrates an exemplary time sequence of input and output signals in an illustrative embodiment;

FIG. 6 illustrates a timing diagram of input and output signals in an illustrative embodiment; and

FIGS. 7-11 illustrate various circuit schematics used for implementing illustrative embodiments.

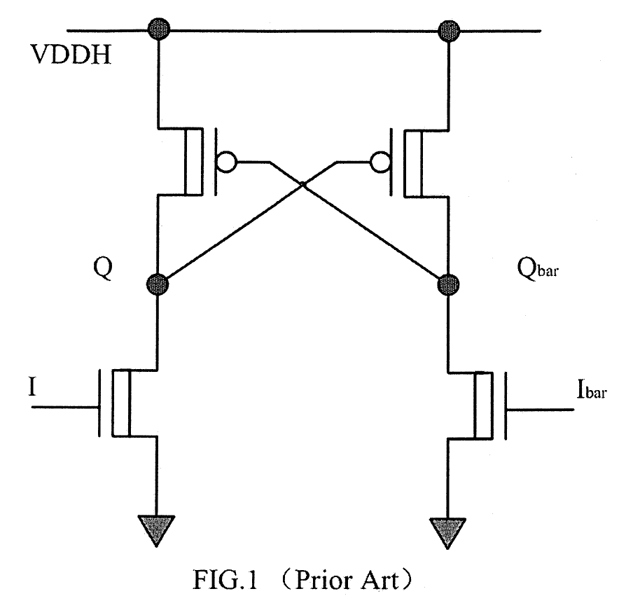

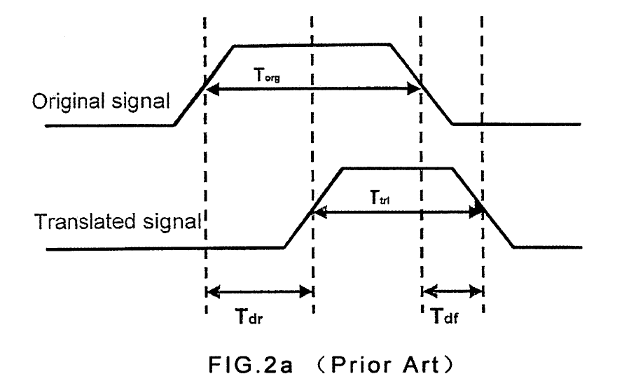

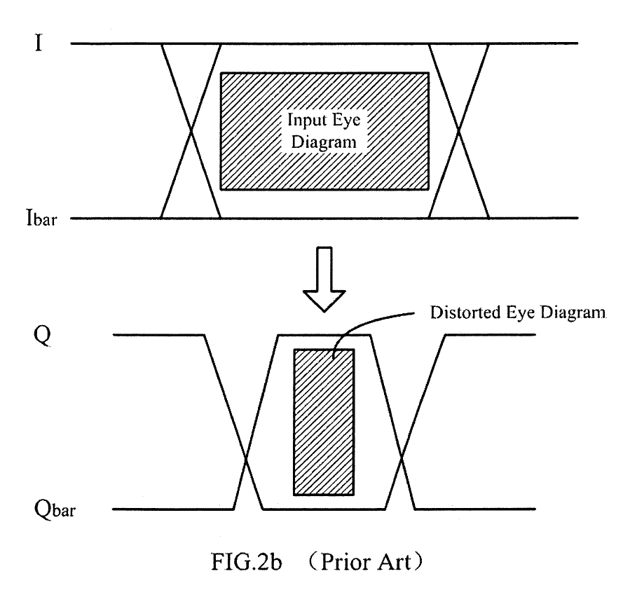

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for eliminating phase distortions in signal communications is provided. The variations of the embodiments of the present invention are discussed. Throughout the various views and illustrative embodiments of the present invention, like reference numbers are used to designate like elements.

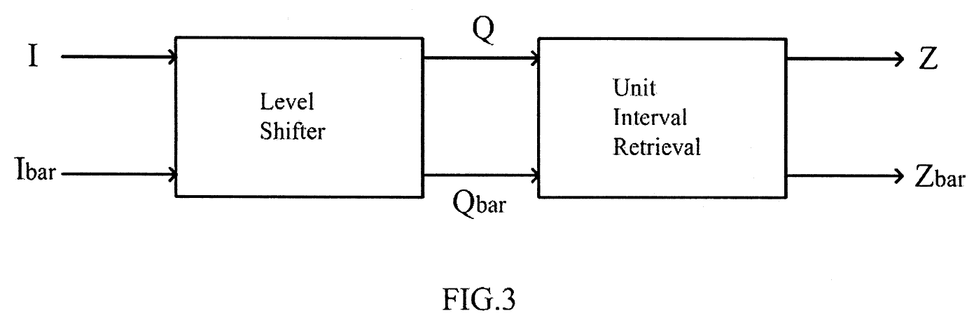

FIG. 3 illustrates a block diagram of an embodiment of the present invention. After input signals I and Ibar pass through a level shifter, as described previously, the undesirable and often inevitable phase distortion is generated in the level shifter due to PVT variations. As a result, complementary output signals Q and Qbar are distorted relative to the input signal I and Ibar. To compensate for the signal degradation and restore the phase of the distorted output signals, the complementary output signals Q and Qbar are input into a unit-interval retrieving circuit, which generates a restored output signal Z and Zbar, or both from the complementary output signals Q and Qbar. Preferably, the restored output signal Z has a unit period, which is substantially the same as the unit period in the input signal I. The unit-interval retrieving circuit has the function of detecting the rising and falling edges of the complementary output signals Q and Qbar, and regenerating the restored output signal Z and Zbar, or both based on the detected rising and falling edges. Please note that throughout the description, the input signal and the output signal are denoted as I and Q, and their complementary signals are denoted as Ibar and Qbar, respectively. However, one skilled in the art will realize that the complementary notations I and Ibar, and Q and Qbar are relative to each other, and can be exchanged.

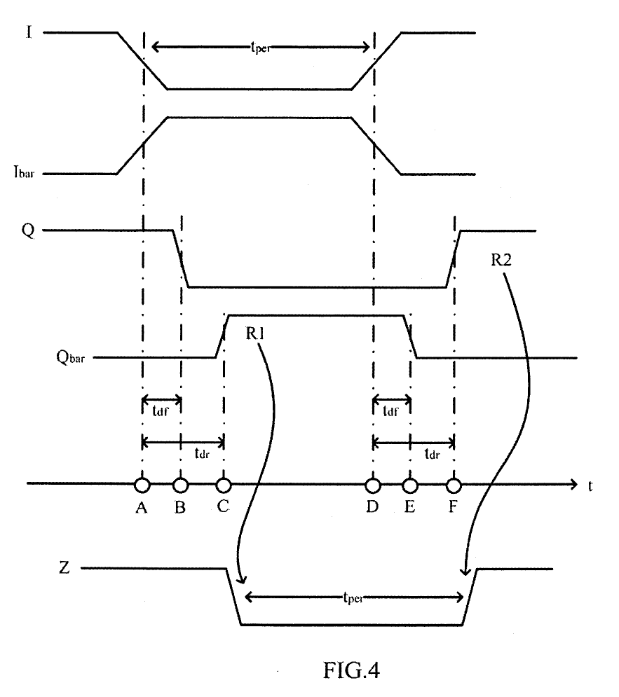

FIG. 4 schematically illustrates exemplary time sequences of input signals I and Ibar and output signals Q and Qbar from a level shifter, wherein the horizontal direction indicates time t. The illustrated exemplary input signal I has a high voltage level (i.e., high state, state 1) in the beginning, and then the signal transits to a low voltage level (i.e., low state, state 0), followed by rising back to state 1. Accordingly, signal I has a unit transition between time points A and D. Assuming the falling point is at time t(A), which is the mid-point of the falling edge of signal I, and further assuming the rising point is at time t(D), which is the mid-point of the rising edge of signal I, the period (or the unit interval) Tₚₑᵣ is t(D)-t(A). Similarly, the inverted input signal Ibar has period Tₚₑᵣ. One skilled in the art will realize that the rising and falling points may be defined at different levels of the respective rising and falling edges rather than the mid-points.

The transitions of the complementary output signals Q and Qbar follow the transitions of input signals I and Ibar. However, due to the delay caused by the level shifting circuit (FIG. 3), the falling mid-point of output signal Q is at time t(B), and the rising mid-point of output signal Q is at time t(F). The rising mid-point of complementary output signal Qbar is at time t(C), and the falling mid-point of complementary output signal Qbar is at time t(E). Relative to the falling mid-point t(A) of input signal I, the falling delay of output signal Q is t_{df}, and the rising delay of complementary output signal Qbar is t_{dr}. Similarly, relative to the rising mid-point t(D) of input signal I, the rising delay of output signal Q is t_{dr}, and the falling delay of complementary output signal Qbar is t_{df}. Therefore, the following equations can be derived:

t(B)=t(A)+t_{df} (Eq. 1)

t(C)=t(A)+t_{dr} (Eq. 2)

t(D)=t(A)+tₚₑᵣ (Eq. 3)

t(E)=t(A)+tₚₑᵣ+t_{df} (Eq. 4)

t(F)=t(A)+tₚₑᵣ+t_{dr} (Eq. 5)

Accordingly, a time difference between time t(E) and time t(B) is:

t(E)−t(B)=(t(A)+tₚₑᵣ+t_{df})−(t(A)+t_{df})=tₚₑᵣ (Eq. 6)

Therefore, the original period tₚₑᵣ of the input signals I and Ibar may be restored by subtracting the falling mid-point t(B) of the signal Q from the falling mid-point t(E) of the complementary signal Qbar.

Similarly, a time difference between time t(F) and time t(C) is:

t(F)−t(C)=(t(A)+tₚₑᵣ+t_{dr})−(t(A)+t_{dr})=tₚₑᵣ (Eq. 7)

The original period tₚₑᵣ (and hence the original phase) of the input signal I may be restored by subtracting the rising mid-point time t(C) of complementary signal Qbar from the rising mid-point time t(F) of signal Q. Please note edges corresponding to time points F and C are in a same direction (both are rising edges), and edges corresponding to time points E and B are in a same direction (both are falling edges).

In other words, the period of the original input signals I and Ibar can be restored from the distorted data path with no or negligible distortion if a unit interval retrieval circuit is added following the distortion-generating level shifting circuit, where the interval retrieval circuit outputs an output signal Z which toggles in response to a rising edge of complementary signal Qbar and a subsequent rising edge of signal Q. For example, in FIG. 4, original input signal I is restored by output signal Z whose falling edge is triggered by the rising edge of complementary signal Qbar (arrow from “R1” in FIG. 4), and whose rising edge is triggered to the rising edge of the signal Q (arrow from “R2” in FIG. 4). While the above is achieved, the output signal Z of the unit interval retrieval circuit restores the period of the original input signal I with no or negligible distortion. In a similar token, the output signal Z of a unit interval retrieval circuit may also restore the period of the original input signal I if Z toggles in response to a falling edge of signal Q and a subsequent falling edge of complementary signal Qbar. As an example, the rising edges of Z respond to the falling edges of the signal Q and the falling edges of Z respond to the falling edges of complementary signal Qbar. In addition, the unit interval retrieval circuit may also output a complementary signal Zbar that represents an original input signal Ibar with negligible phase distortion. Preferably, complementary signal Zbar is a mirrored version of output signal Z in signal time t, but the various embodiments of the present invention are not limited to only symmetric representation between output signals Z and Zbar.

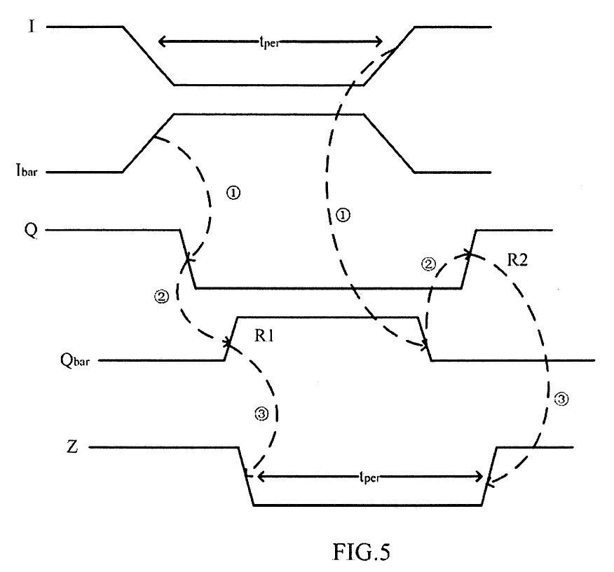

FIG. 5 illustrates an exemplary time sequence of input signals I and Ibar, and output signals Q and Qbar from the level shift circuit, and the output signal Z from the unit interval retrieval circuit of an embodiment of the present invention, illustrated with respect to FIG. 3. In the current embodiment, the output signal Q from the level shifting circuit is set low in response to a rising edge of complementary input signal Ibar, the complementary output signals Qbar is set high by the falling edge of the output signal Q, and the output signal Z is set low in response to the rising edge of complementary signal Qbar. In contrast, a rising edge of the input signal I sets the complementary output signal Qbar to low, which in turn sets the output signal Q to high. Output signal Z of the unit interval retrieval circuit is set to high in response to the rising edge of output signal Q. As a result, the period of the output signal Z is “clipped” from the input signal I stream, and restores the period of the original input signal I with no or negligible distortion.

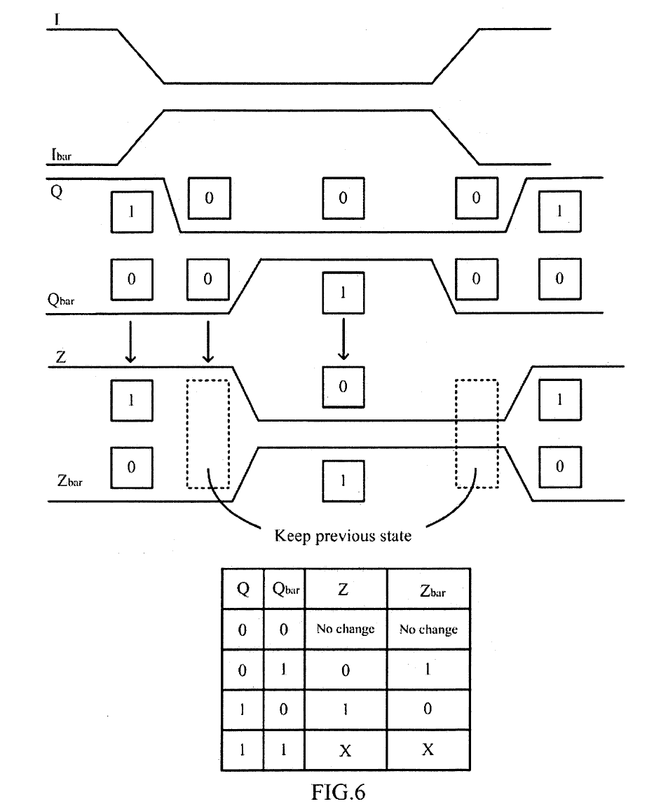

FIG. 6 illustrates an exemplary timing diagram of I and Ibar, output signals Q and Qbar, and the output signal Z and Zbar from a digital logic perspective. Logic states 0 and 1 are used to indicate the voltage levels of the various signals. It is revealed from the preferred embodiments that the following relationship between the logic states of the various signals holds valid in order for the output signal Z and Zbar of unit interval retrieval circuit to restore the period of the original input signals I and Ibar after I and Ibar pass the distorting level shifting circuit. From left to right in the timing diagram of FIG. 6, the output signal Z changes to state 1 and the complementary output signal Zbar changes to state 0 when signal Q is at state 1 and Qbar is at state 0. The states of Z and Zbar remain unchanged when Q changes from state 1 to state 0. The output signal Z changes to state 0 and the complementary signal Zbar changes to state 1 on the rising edge of signal Qbar from state 0 to state 1, while signal Q remains at state 0. While signal Qbar changes from state 1 to state 0, the states of Z and Zbar remain unchanged. The output signal Z changes to state 1 and the complementary output signal Zbar changes to state 0 on the rising edge of signal Q from state 0 to state 1, while signal Qbar remains at state 0.

The logic operation of the unit interval retrieval circuit in preferred embodiments is summarized in the excitation table in FIG. 6. The excitation shows the state transition for each combination of excitation inputs. Columns Q and Qbar are the output signals of the distorting level shifting circuit. Signals Q and Qbar are applied to the unit interval retrieval circuit. The column Z and Zbar are the states of the unit interval retrieval circuit after Q and Qbar are applied as inputs and a steady state has been achieved. It is noted that state 1 signals on both Q and Qbar are generally not existing in reality, thus the output signals Z and Zbar are labeled as “X” (i.e., not allowed) under this input combination.

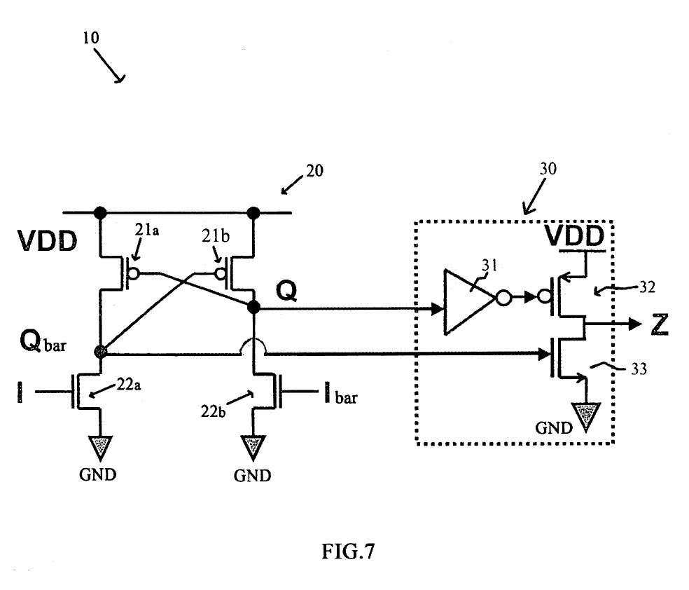

FIG. 7 illustrates an exemplary voltage level converter 10 implementing the logic operation described above. In the current embodiment, voltage level converter 10 comprises differential amplifier circuit 20, and unit interval retrieval circuit 30. The differential amplifier circuit 20 comprises four cross-connected metal-oxide-semiconductor field effect transistors (MOSFETs), i.e., a first and a second p-channel MOSFET 21a and 21b, and a first and a second n-channel MOSFET 22a and 22b. P-channel MOSFETs 21a and 21b are a symmetric pair, and so are n-channel MOSFETs 22a and 22b. The sources of the first and second p-channel MOSFETs 21a and 21b are coupled to the power supply (VDD), and the sources of the first and second n-channel MOSFETs 22a and 22b are grounded (GND). The input signals I and its complementary Ibar of the level converter 10 are applied to the gates of the n-channel MOSFETs 22a and 22b, respectively. The drain of the second n-channel MOSFET 22b is connected to a first output signal Q, as are the gate of the first p-channel MOSFET 21a and the drain of the second p-channel MOSFET 21b. In a similar manner, complementary output signal Qbar is connected to the drain of the first n-channel MOSFET 22a, as well as to the gate of the second p-channel MOSFET 21b, and to the drain of the first p-channel MOSFET 21a. After passing amplifier circuit 20, the input signals I and Ibar are converted into output signals Q and Qbar, which are typically distorted as explained previously.

Signals Q and complementary signal Qbar are then supplied to unit interval retrieval circuit 30. Signal Q is coupled to an input of an inverter 31, whose output is connected to the gate of a third p-channel MOSFET 32. Complementary signal Qbar is coupled to the gate of a third n-channel MOSFET 33. The source of the third p-channel MOSFET 32 is coupled to VDD, while the source of the third n-channel MOSFET 33 is coupled to GND. Output signal Z of unit interval retrieval circuit 30 is connected to the drains of the third p-channel MOSFET 32 and the third n-channel MOSFET 33. Output signal Z may restore the period of the original input signal I with no or negligible distortion as explained above.

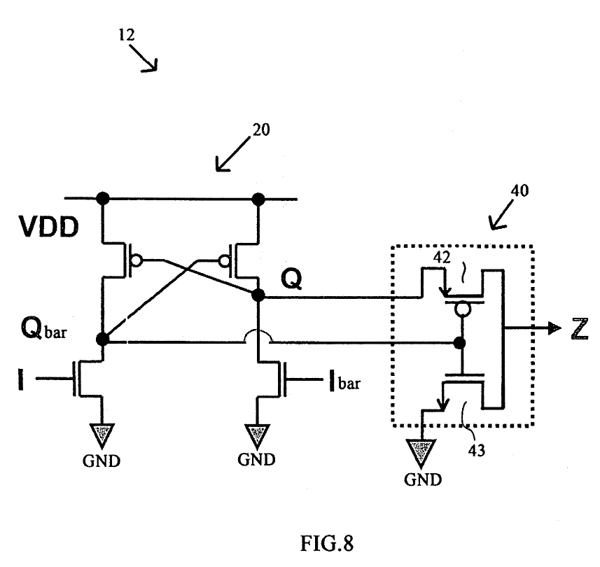

FIG. 8 illustrates voltage level converter 12 in another preferred embodiment, which comprises differential amplifier circuit 20 and unit interval retrieval circuit 40. Differential amplifier circuit 20 is similar to that described with respect to FIG. 7 and will not be described herein to avoid repetition. Signal Q outputted from amplifier circuit 20 is coupled to the source of a third p-channel MOSFET 42, while complementary signal Qbar is connected to the gates of the third p-channel MOSFET 42 and a third n-channel MOSFET 43. The source of the third n-channel MOSFET 43 is grounded. Output signal Z of unit interval retrieval circuit 40 is drawn from the drains of the third p-channel MOSFET 42 and the third n-channel MOSFET 43.

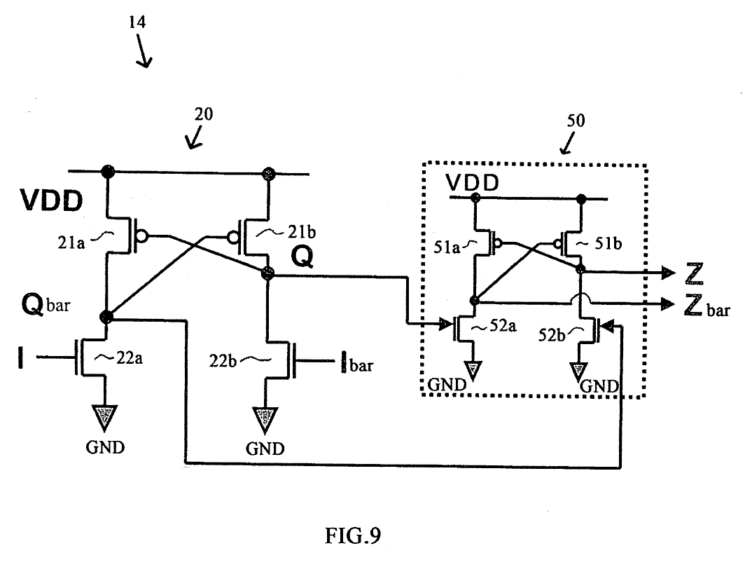

FIG. 9 illustrates voltage level converter 14 in a further preferred embodiment, which comprises differential amplifier circuit 20 and unit interval retrieval circuit 50. Differential amplifier circuit 20 is similar to that described with respect to FIG. 7 and will not be described herein to avoid repetition. Unit interval retrieval circuit 50 in this embodiment is a duplicate of differential amplifier circuit 20, where signal Q and Qbar outputted from amplifier circuit 20 are provided as input signals of unit interval retrieval circuit 50 on the gates of n-channel MOSFETs 52a and 52b, respectively. The sources of p-channel MOSFETs 51a and 51b are tied to VDD, while the sources of n-channel MOSFETs 52a and 52b are grounded. The output signal Z is drawn from the node coupling to the drains of p-channel MOSFET 51b and n-channel MOSFET 52b. The complementary output signal Zbar is drawn from the node coupling to the drains of p-channel MOSFET 51a and n-channel MOSFET 52a.

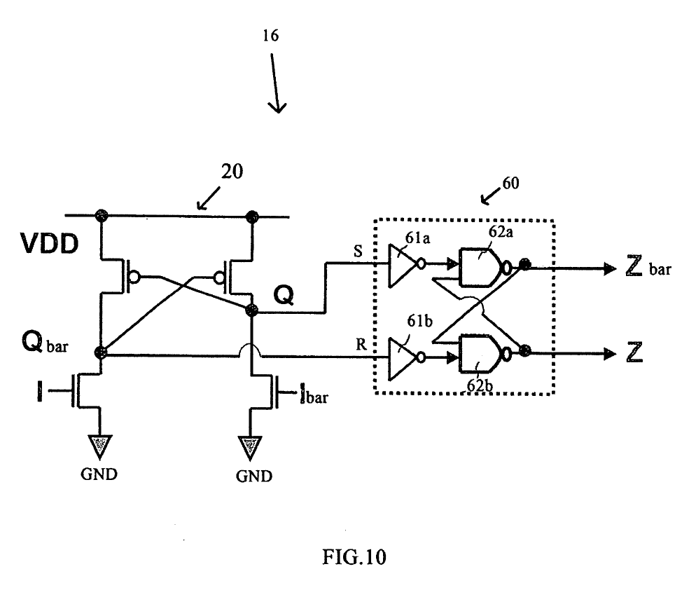

FIG. 10 illustrates voltage level converter 16 in an additional preferred embodiment, which comprises differential amplifier circuit 20 and unit interval retrieval circuit 60. Differential amplifier circuit 20 is similar to that described with respect to FIG. 7 and will not be described herein to avoid repetition. Unit interval retrieval circuit 60 in this embodiment is a set-reset (SR) latch, where output signal Q from differential amplifier circuit 20 is coupled to the S node of SR latch 60, while the complementary output signal Qbar from differential amplifier circuit 20 is coupled to the R node of SR latch 60. SR latch 60 in the current embodiment is implemented through inverters 61a and 61b, and NAND gates 62a and 62b in a configuration shown in FIG. 10. After distorted signals Q and Qbar passing through SR latch 60, the output signals Z and Zbar restore the period of the original input signal I and Ibar with no or negligible signal distortion.

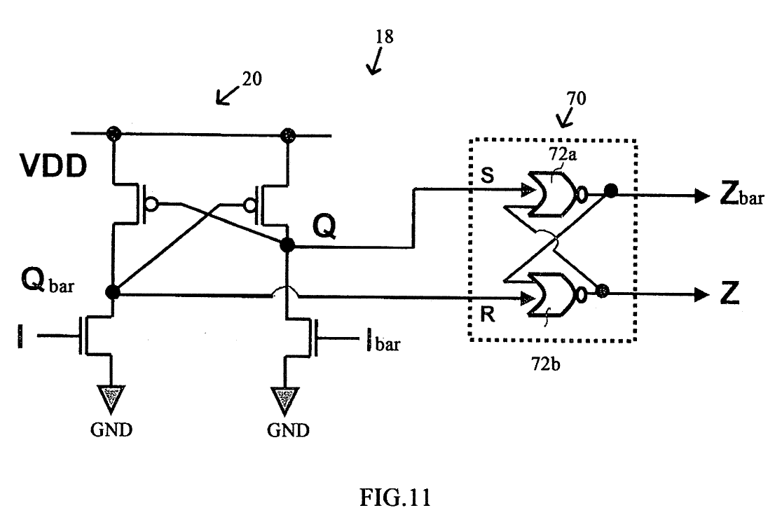

FIG. 11 illustrates voltage level converter 18 in an additional preferred embodiment, which comprises differential amplifier circuit 20 and unit interval retrieval circuit 70. Differential amplifier circuit 20 is similar to that described with respect to FIG. 7 and will not be described herein to avoid repetition. Unit interval retrieval circuit 70 comprises an SR latch implemented through NOR gates as shown. The output signal Q from differential amplifier circuit 20 is coupled to the S node of SR latch 70, while the complementary output signal Qbar from amplifier circuit 20 is coupled to the R node of SR latch 70. After distorted signals Q and Qbar passing through SR latch 70, the output signals Z and Zbar restore the period of the original input signal I and Ibar with no or negligible signal distortion.

It should be noted that only a limited number of embodiments are shown for illustrative purposes. However, those of ordinary skill in the art will appreciate that, in practice, many more digital or analog circuitries may be employed to implement the inventive features described, for example, with respect to FIGS. 4-6. The specific circuit configurations or lack of circuit configurations illustrated herein to realize the inventive features are not intended to limit the embodiments of the present invention in any way.

Also, although the voltage level converters in the illustrative embodiments are implemented in CMOS processing technology, various other suitable IC processing technologies, such as bipolar and BiCMOS processes, may be also used to construct the circuit configurations in preferred embodiments. The circuit configurations of the various voltage level converters in the illustrative embodiments are not intended to limit the inventive features to any specific IC processing technologies in any way.

The preferred embodiments of the present invention have several advantageous features. The phase distortion may be significantly reduced, and possibly substantially eliminated. The embodiments of the present invention support both data and clock duty cycle corrections, and are substantially immune to process variations.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A voltage level converting circuit comprising:
a voltage level shifting circuit responding to a first input voltage signal and a second input voltage signal and outputting a third and a fourth voltage signals, wherein the first input voltage signal and the second voltage signal are at a first voltage level and complementary to each other, and wherein the third and the fourth voltage signals are at a second voltage level; and
a unit interval retrieval circuit responding to the third and the fourth voltage signals and outputting a fifth voltage signal at the second voltage level, wherein the period of the fifth voltage signal is substantially similar to that of the first voltage signal.

2. The voltage level converting circuit of claim 1, wherein the fifth voltage signal comprises a rising edge and a falling edge, wherein a rising edge of the fifth voltage signal is triggered by and substantially aligned with a rising edge of the third voltage signal, and wherein a falling edge of the fifth voltage signal is triggered by and substantially aligned with a rising edge of the fourth voltage signal.

3. The voltage level converting circuit of claim 2, wherein the rising edge of the fourth voltage signal is triggered by a falling edge of the third voltage signal, and the falling edge of the third voltage signal is triggered by a rising edge of the second input voltage signal, and wherein the rising edge of the third voltage signal is triggered by a falling edge of the fourth voltage signal, and the falling edge of the fourth voltage signal is triggered by a rising edge of the first input voltage signal.

4. The voltage level converting circuit of claim 1, wherein the second voltage level is higher than the first voltage level.

5. The voltage level converting circuit of claim 1, wherein the unit interval retrieval circuit further outputs a sixth voltage signal at the second voltage level, the sixth voltage signal being complementary to the fifth voltage signal.

6. The voltage level converting circuit of claim 1, wherein the voltage level shifting circuit comprises a first differential amplifier, and wherein the first and the second input voltage signals are coupled to the gate of a first and a second n-channel metal-oxide-semiconductor field effect transistors (MOSFETs) of the differential amplifier, respectively.

7. The voltage level converting circuit of claim 6, wherein the third voltage signal is drawn from a first node coupled to the drain of the first n-channel MOSFET and the drain of a first p-channel MOSFET, and wherein the fourth voltage signal is drawn from a second node coupled to the drain of the second n-channel MOSFET and the drain of a second p-channel MOSFET.

8. The voltage level converting circuit of claim 7, wherein the unit interval retrieval circuit comprises a second differential amplifier, and wherein the third and the fourth voltage signals are coupled to the gate of a third and a fourth MOSFETs of the second differential amplifier, respectively, and wherein the fifth voltage signal is drawn from a third node coupled to the drain of the third n-channel MOSFET and the drain of a third p-channel MOSFET.

9. The voltage level converting circuit of claim 1, wherein the unit interval retrieval circuit comprises a third n-channel in serial with a third p-channel MOSFETs, wherein the gate of the third p-channel is coupled to an inverter driven by the third voltage signal, wherein the gate of the third n-channel is driven by the fourth voltage signal, and wherein the fifth voltage signal is drawn from a node coupled to the drains of the third n-channel and the third p-channel MOSFETs.

10. The voltage level converting circuit of claim 1, wherein the unit interval retrieval circuit comprises a third n-channel MOSFET in serial with a third p-channel MOSFET, wherein the source of the third p-channel MOSFET is coupled to the third voltage signal, wherein the gates of the third n-channel and the third p-channel MOSFETs are driven by the fourth voltage signal, and wherein the fifth voltage signal is drawn from a node coupled to the drains of the third n-channel MOSFET and the third p-channel MOSFET.

11. A voltage level converting circuit comprising:
a voltage level shifting circuit generating a first voltage signal and a second voltage signal in response to mutually complementary input voltage signals, the first voltage signal and the second voltage signal having a different voltage level from the input voltage signals;
a unit interval retrieval circuit responding to the first voltage signal and the second voltage signal and outputting a first output voltage signal having a period substantially similar to that of the input voltage signals;
wherein a first voltage state of the first voltage signal and a second voltage state of the second voltage signal set the first output signal to the first voltage state.

12. The voltage level converting circuit of claim 11, wherein the first voltage state is a high voltage state and the second voltage state is a low voltage state, and wherein a rising edge of the second voltage signal triggers the first output signal to change from a high voltage state to a low voltage state.

13. The voltage level converting circuit of claim 11, wherein the first voltage state is a low voltage state and the second voltage state is a high voltage state, and wherein a rising edge of the first voltage signal triggers the first output signal to change from a low voltage state to a high voltage state.

14. The voltage level converting circuit of claim 11, wherein the first output signal remains at a previous voltage state when the first and the second voltage signals are at a same voltage state.

15. The voltage level converting circuit of claim 11, wherein the unit interval retrieval circuit further outputs a second output voltage signal complementary to the first output signal.

16. The voltage level converting circuit of claim 11, wherein the unit interval retrieval circuit comprises a set-reset (SR) latch with its S node coupled to the first voltage signal and its R node coupled to the second voltage signal.

17. The voltage level converting circuit of claim 11, wherein the voltage level shifting circuit and the unit interval retrieval circuit comprise bipolar, CMOS, or BiCMOS circuitry.

18. A voltage level converting circuit comprising:
a voltage level shifting circuit responding to a first input voltage signal and a complementary second input voltage signal at a first voltage level and outputting a third voltage signal and a complementary fourth voltage signal at a second voltage level; and
a unit interval retrieval circuit responding to the third voltage signal and the complementary fourth voltage signal and outputting a first output voltage signal at the second voltage level, the period of the first output voltage signal being substantially similar to that of the first input voltage signal;
wherein a rising edge of the second input signal triggers the third voltage signal to change from a high voltage state to a low voltage state, which triggers the fourth voltage signal to change from a low voltage state to a high voltage state, which triggers the first output voltage signal to change from a high voltage state to a low voltage state;
wherein a rising edge of the first input signal triggers the fourth voltage signal to change from a high voltage state to a low voltage state, which triggers the third voltage signal to change from a low voltage state to a high voltage state, which triggers the first output voltage signal to change from a low voltage state to a high voltage state.

19. The voltage level converting circuit of claim 18, wherein the voltage level shifting circuit comprises a differential amplifier adapted to convert the first input voltage signal and the second input voltage signal to the third voltage signal and the fourth voltage signal.

20. The voltage level converting circuit of claim 18, wherein the unit interval retrieval circuit comprises a circuit configuration selected from the group consisting of a complementary MOSFETs, a differential amplifier, an SR latch, and combinations thereof.
